(19) United States
(12) Patent Application Publication
(10) Pub. No.: US 2009/0114370 A1
(43) Pub. Date: May 7, 2009

(54) METHOD AND SYSTEM FOR USING THE WASTE HEAT OF A COMPUTER SYSTEM

(76) Inventor: Christoph Konig, Ottobrunn (DE)

Correspondence Address: HAYES SOLOWAY P.C., 3450 E. SUNRISE DRIVE, SUITE 140, TUCSON, AZ, 85718, US

(21) Appl. No.: 12/264,803

(22) Filed: Nov. 4, 2008

(30) Foreign Application Priority Data
Nov. 6, 2007 (DE) 102007053220.4
Dec. 21, 2007 (DE) 102007062143.6

(51) Int. Cl. F24H 9/00; F25B 27/00; H05K 7/20

(52) U.S. Cl. 165/47; 62/238.3; 361/688

(57) ABSTRACT

A method for using the waste heat of a computer system with a plurality of processors comprises the following steps. Jobs in the computer system are distributed to the processors in such a way that processors of a first group of processors are operated with a high processor load and processors of a second group of processors are operated with only a minimal processor load. In another method, waste heat is dissipated from the processors by a cooling device, wherein the waste heat dissipated from the processors is regulated in such a way that the processor assumes a temperature that is greater than a given minimum temperature. In both cases, the waste heat of the processors is transferred to a device for using the waste heat.

### BACKGROUND OF THE INVENTION

The invention relates to a method and a system for using the waste heat of a computer system with a plurality of processors.

Modern computer systems, for example, so-called server farms, can have up to a few thousand processors. In light of an increasing demand for network services, it is foreseeable that the number of processors in future systems will continue to rise. With increasing performance of the individual processors, their demand for electrical power also increases. Taken together, this results, first, in an enormous primary energy demand (power consumption) for larger computer systems and, second, in a large amount of generated heat that must be transported out of the computer system via suitable cooling devices. Frequently, for the dissipation of heat out of the computer system, additional primary energy is required, for example, through the use of compressor air-conditioning systems for climate control of the rooms in which the computer system is set up. On the other hand it is known to at least partially reuse the primary energy used for the computer system, for example, by coupling the waste heat via heat exchangers into a heating system or a system for generating hot water. Assuming that there is a need for heating heat or hot water, the total energy demand of the computer system and the surrounding office building can be reduced.

### SUMMARY OF THE INVENTION

One object of the invention is to devise a method and a system that use the waste heat of a computer system with a plurality of processors in various ways with high efficiency.

This object is achieved by the features of the independent claims. Improvements and advantageous constructions are specified in each dependent claim.

According to a first aspect of the invention, the object is achieved by a method for using waste heat of a computer system with a plurality of processors with the following steps: jobs in the computer system are distributed to the processors in such a way that processors of a first group of processors are operated with a high processor load and processors of a second group of processors are operated with only a minimal processor load. The waste heat of the processors is transferred to a device for using the waste heat.

According to a second aspect of the invention, the problem is solved by a method for using waste heat of a computer system with a plurality of processors with the following steps: the waste heat from the processors is dissipated by a cooling device, wherein the amount of heat dissipated from the processors is regulated in such a way that the processor assumes a temperature that is greater than a given minimum temperature. The waste heat of the processors is transferred in turn to a device for using the waste heat.

Both aspects of the invention exploit the fact that the higher the temperature level at which this waste heat is made available, the greater the efficiency, with which it can be used. For example, for the use of waste heat by a thermodynamic Carnot cycle, a maximum efficiency of η=1−Th/Tk can be achieved. Here, Th indicates the temperature level at which the waste heat is made available, and Tk indicates the temperature level to which a working medium is cooled by a cooling device in the thermodynamic cycle. An economical cooling method is here typically associated with the temperature of the ambient air or the temperature of a cold-water influx, so that only a small variation is possible for the value of Tk. According to the invention, a high efficiency η is achieved in that the temperature Th at which the waste heat is dissipated from the computer system is increased as much as possible.

According to the first aspect of the invention, a high temperature level for the waste heat is achieved in such a way that jobs in the computer systems are distributed to various processors so that at least two groups of processors are formed, wherein the processors of the first group are operated with a high processor load.

The consumed electrical power of a processor depends on the voltage and the clock rate at which the processor is operated. Furthermore, the consumed electrical power increases with the processor load, because null-operations executed by a not completely loaded processor lead to a lower power consumption of the processor than other operations. The temperature set on a processor results from the consumed electrical power and also the amount of heat dissipated per unit time (cooling power). Consequently, for a given heat removal, the temperature of the processors of the first group increases with increasing processor load.

In contrast, the second group of processors is operated with the lowest possible processor load, so that they require the smallest possible amount of energy. In addition, in a preferred implementation of the invention, it is possible to reduce the clock rate and the voltage at which these processors are operated relative to normal operation, in order to further reduce their power consumption. In contrast to the typical method of distributing jobs within a computer system to the processors as uniformly as possible, according to the invention, the goal is the most inhomogeneous distribution of jobs possible to the processors of the first and the second group of processors.

According to the second aspect of the invention, a high temperature level for the waste heat of the individual processors is achieved in that the transfer of waste heat from the processors through the cooling device is limited so that, for a given processor load and the resulting consumed electrical power, at least a given minimum temperature is set. If the minimum temperature is selected sufficiently high, an efficient use of the waste heat can be realized. Preferably, the minimum temperature, specified in ° C., can equal, for example, more than 80% of the maximum temperature, specified in ° C., permissible for the processors. In this way, a temperature level of the waste heat of 70° to 100° C. can be achieved, without causing error functions of the processors or shortening of their lifetime.

Optionally, the two methods presented that can keep waste heat at a high temperature level can also be used together.

According to a third aspect of the invention, the problem is solved by a system that has a computer system with a plurality of processors, a cooling device for dissipating the waste heat of at least one part of the processors, and a device for making use of the waste heat of the processors. The system is here designed for carrying out a method named above. The advantages of the third aspect correspond to those of the first and second aspects.

### BRIEF DESCRIPTION OF THE DRAWINGS

The invention is explained in more detail below with reference to embodiments with the aid of three figures.

Shown are:

FIG. 1 shows a computer system with a plurality of processors and a cooling device for making use of the waste heat of the processors,

FIG. 2 shows a flow chart of a method for distributing jobs to processors of a computer system, and

FIG. 3 shows a cooling device for making use of the waste heat of processors of a computer system.

### DETAILED DESCRIPTION OF PREFERRED EMBODIMENTS

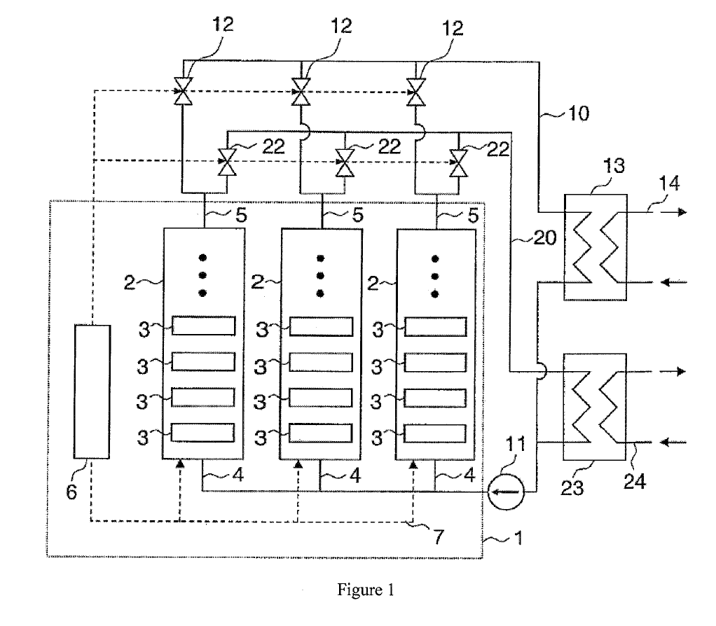

FIG. 1 shows schematically a computer system 1 that has a plurality of servers each with one or more processors 3 in several server cabinets 2. Furthermore, in the computer system there is a scheduler 4 for distributing jobs to the processors 3 of the computer system 1. The scheduler 4 is connected via a management network 5 to the processors of the computer system 1. Each server cabinet 2 is attached via a coolant inlet 6 and a coolant outlet 7 to a coolant circuit 10 with a coolant pump 11, valves 12, and a heat exchanger 13. The heat exchanger 13 thermally couples the coolant circuit 10 to a utilization circuit 14. In addition, another coolant circuit 20 is provided that is similarly connected to the server cabinets 2. The other coolant circuit 20 has an additional coolant pump 21, additional valves 22, and an additional heat exchanger 23. The additional coolant circuit 20 is thermally coupled via this additional heat exchanger to an additional utilization circuit 24. For control, the valves 12 and the additional valves 22 are connected to the scheduler 6.

The computer system 1 shown in FIG. 1 represents, for example, a so-called server farm or part of a server farm. Instead of the server cabinets 2, also called server racks, the computer system 1 can also be divided into other sub-units, for example, into individual computers, servers, or processors 3 with respect to the connection to the coolant circuits 10, 20. With such a sub-division, the method described below can also be transferred analogously to other computer systems with a plurality of processors as server farms.

For cooling the processors 3, a cooling device is provided with liquid cooling. For this purpose, each server cabinet 2 has the coolant inlet 6 and the coolant outlet 7. By means of this inlet and outlet, coolant, for example, water is fed to the processors 3 and transferred away from the processors, respectively, for liquid cooling.

Within the server cabinets 2, not-shown heat exchangers are provided that absorb the waste heat of the processors 3 and transfer it to the coolant. For better differentiability of the heat exchangers 13 and 23, the heat exchangers that absorb the waste heat of the processors 3 are designated below as heat absorbers. These heat absorbers can be thermally coupled either directly to the processors 3 or also via a heat-conductive element, for example, a heat pipe. It is conceivable to provide a heat absorber for each processor 3 or also to connect one group of processors 3, for example, all of the processors 3 of a server, thermally to a heat absorber. Preferably, all of the heat absorbers of one server cabinet 2 are arranged in parallel with respect to the coolant flow. In individual cases, for example, for reasons of redundancy, if an equivalent processor is provided for a processor 3 and if the processor 3 and its equivalent processor are typically not operated at the same time, a series connection of the heat absorber to these processors 3 is also conceivable.

By means of the valves 12 or the additional valves 22, the coolant outlet 7 of each server cabinet 2 can be connected either to the coolant circuit 10 or to the additional coolant circuit 20. The waste heat generated by the processors 3 of each server cabinet 2 and absorbed by the coolant can thus be fed either to the heat exchanger 13 or to the additional heat exchanger 23. In the embodiment, the return of the coolant from the heat exchanger 13 and the additional heat exchanger 23 is realized together via the coolant pump 11 to the inlets 4 of the server cabinets 2. Alternatively, it is also possible to provide a coolant pump for each coolant circuit 10, 20 and to also provide such valves in the inlet branch analogous to the valves 12 and the additional valves 22 in the outlet branch of the coolant from the server cabinets 2.

In the heat exchangers 13 or 23, the waste heat of the processors 3 is transferred into the utilization circuits 14 or 24 in order to use the waste heat. The utilization circuits 14, 24 can be, for example, water circuits of a heating system or a hot-water generator. It is also conceivable that the utilization circuits 14, 24 are working medium circuits of a thermodynamic cycle. For example, an absorption-type refrigerating machine can be driven by this cycle, wherein the cooling power generated in this way from the waste heat of the processors 3 can be used for climate control of the rooms in which the computer system 1 is housed. It is also conceivable to use the waste heat of the processors 3 for generating steam and subsequent conversion of the heat energy into mechanical energy in a steam turbine in the thermodynamic cycle. The electrical energy generated by a generator coupled to the steam turbine can be used to partially cover the primary energy demand of the computer system 1. For converting the waste heat of the processors 3 into mechanical energy, in particular, the so-called Kalina process is suitable. In this process, it is possible to generate steam at a relatively low temperature level through the use of an ammonia-water mixture as the working medium of the cycle.

The task of the scheduler 4 is to distribute jobs, also called tasks or processes, to be executed in the computer system I to the individual processors 3. Here, the scheduler 4 can be executed on a computer provided separately for management purposes within the computer system 1. It is also conceivable, however, that the jobs of the scheduler 4 are performed centrally by one of the processors 3 of the server of the computer system I or decentralized by several of the processors 3.

The scheduler 4 is designed to distribute arising jobs to the processors 3 so that a part of the processors 3 is operated with a processor load as high as possible, while another part of the processors 3 is operated with a processor load as low as possible.

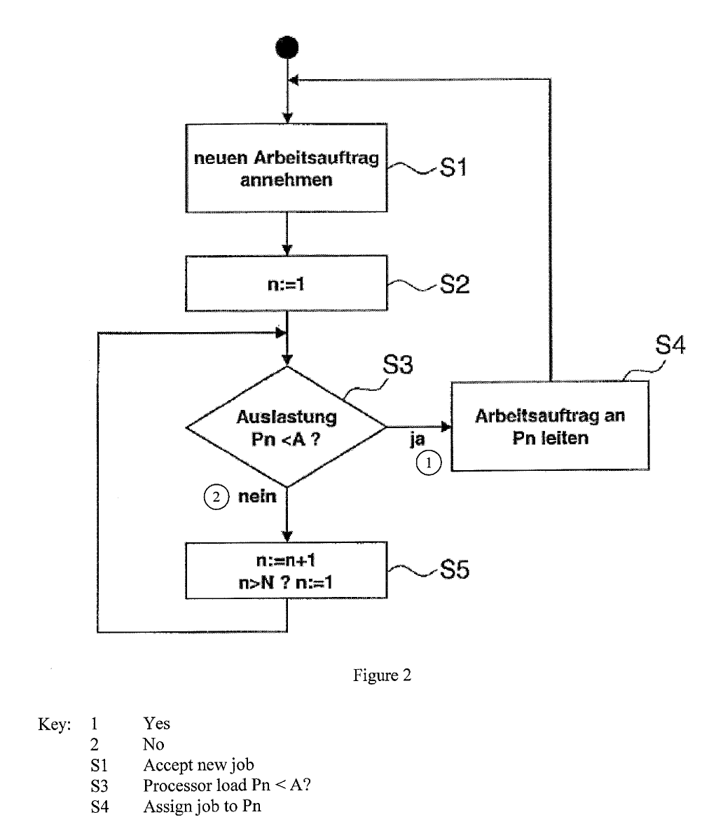

In a flow chart, FIG. 2 shows a greatly simplified embodiment of a work method for the scheduler 4. This method produces a distribution as uneven as possible in the work load of the processors 3 of the computer system 1.

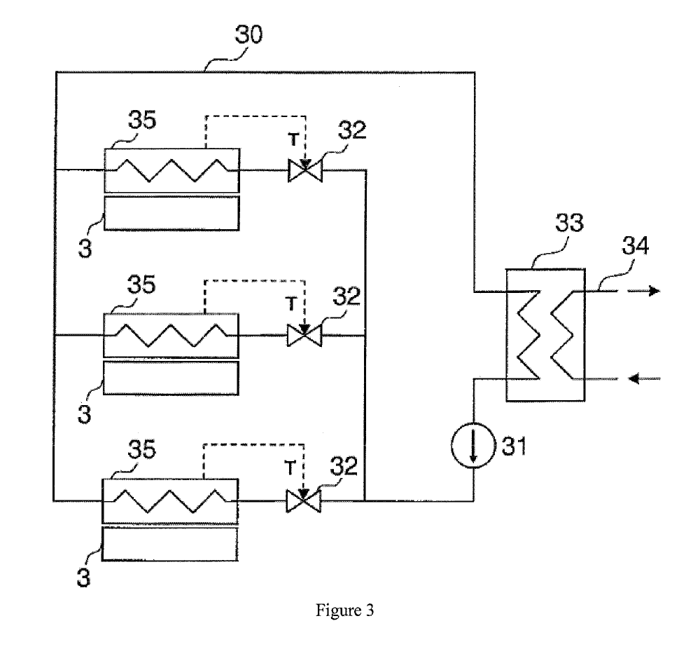

In a first step S1, the scheduler 4 accepts a new job. As an example, the computer system I has available a number N of processors 3. The individual processors 3 are numbered in ascending order so that the processors 3 of the individual server cabinets 2 are assigned continuous number blocks. In a step S2, a variable n for indexing the individual processors 3 is set to the initial value 1. In a subsequent step S3, the processor load of the processor 3 assigned to the number n is checked. In FIG. 3, this processor 3 is designated as Pn. If the processor load of the processor with the number n is less than a given processor load A, the job is transmitted to this processor 3 with the number n for execution. The method then branches back to step S1 for receiving new jobs. In contrast, if it was determined in step S3 that the processor load of the processor with the number n already is above the given processor load, in step S5 the indexing variable n is incremented by 1 and reset to the value 1 if n should be greater than N after incrementation. Then, step S3 is 22 repeated with the new value of the indexing variable n.

By means of the method, the processors 3 are divided into two groups of processors of which the processors 3 of the first group are operated with a processor load greater than A, while the processors of the second group are loaded only minimally or not at all. If n* indicates the value at which in step S4 the last job was transmitted to the processor with the number n*, the processors with the numbers 1 to n*−1 are consequently operated with a processor load greater than A and form the first group, while the processors with the numbers n* to N are operated with only a small processor load and form the second group. The limit n* here shifts dynamically with the provided work volume.

In alternative implementations of the method, it can be provided to change the numbering of the processors 3 or the sequence in which the processor load of the processors is queried from time to time so that the same processors 3 are not always assigned to the first group. In this way the processors 3 are loaded uniformly in an averaged way over their lifetime. Furthermore, it is conceivable that the actual temperature of a processor is incorporated into the distribution method.

For saving primary energy, the processors 3 of the second group can be operated with a reduced voltage and reduced clock rate relative to normal operation. Certain processes that are carried out in the computer system I must be executed, in principle, on each processor 3, for example, processes for the internal management of the server, for maintaining the operating readiness of the server, or for providing an operating system on each server. These processes lead to a base load also on the processors 3 of the second group.

Advantageously, this base load can be reduced in that the computer system 1 is operated completely or partially with computers that provide virtual machines. Different users can process jobs independently and separately from each other on computers with virtual machines, often also called virtual machine systems. In virtual machine systems, the hardware resources of a common-use computer or computer system are divided into several virtual environments, the so-called virtual machines. To the user or users, virtual machines are presented as standalone, independent units. In this context, independent means that different operating systems with a wide range of different applications, programs, or scripts can be executed on the individual virtual machines. Here, the virtual machines are partitioned from each other, so that access from one virtual machine to the resources (for example, memory region) used by another virtual machine is not possible.

If a user does not claim the entire computational power of a computer, for example, a server, the applications of the user can be executed on a virtual machine. Several such users can then share a server having several virtual machines, without this leading to negative effects on applications in terms of quality or security for the user. If a server farm (or, in general, a computer system with several processors 3) is underutilized, then for the different users, partitioned work environments (for example, operating systems) can be provided that can be executed, however, on fewer servers (or, in general, computers or processors 3) than partitioned work environments. The work power generated by the computer system can be concentrated on a few processors (the processors 3 of the first group). The processors that are not needed (processors 3 of the second group) can then be completely turned off or set into a state consuming only little current. The total power consumption of the computer required for providing the operating systems thus can be reduced.

It is also possible to design a virtual machine system that controls the computational power of a variable number of computer systems, and this provides in turn a similarly variable number of users in partitioned work environments. In such a case, at any time an arbitrary work power can be provided to each user within the scope of the total available work power of the computer system. In turn, all of the processors not called on (processors 3 of the second group) can be turned off simultaneously.

In the embodiment of FIG. 1, the scheduler 4 controls, as another task, the valves 12 and the additional valves 22. One of the valves 12 and one of the additional valves 22 that are allocated to a server cabinet 2 is open while the other is closed. As a function of the processor load of the computer system 1, now those server cabinets 2 in which all of the processors 3 belonging to the first group of processors with high processor load are connected to the coolant circuit 10 and all of the other server cabinets 2 are connected to the additional coolant circuit 20.

According to the separation of the processors 3 into the first group of highly loaded processors 3 and the second group of only minimally loaded processors 3, a high temperature of the coolant in the coolant outlet 7 is set for the server cabinets 2 in which all of the processors 3 are operated with a high processor load. Accordingly, in the utilization circuit 14, waste heat is provided at a high temperature level, while in the utilization circuit 24, waste heat is provided at a lower temperature level.

The waste heat at a lower temperature level in the utilization circuit 24 can be used for those applications in which a low temperature is sufficient, for example, for heating purposes or for generating hot water. In an alternative implementation, it can also be provided that the waste heat arising at the low temperature level is discarded; for example, it is dissipated to the surrounding air.

In contrast, the waste heat provided at a high temperature level can be used advantageously and efficiently in the utilization circuit 14 for those processes that require a correspondingly high temperature level or whose efficiency increases with increasing temperature. These are, in particular, thermodynamic cycles for operating a heat engine for generating power or for operating an absorption-type refrigerating machine. Through the distribution of the jobs within the computer system 1, waste heat generated at a high temperature level can be processed separately from waste heat at a lower temperature level. Because the efficiency of the conversion of waste heat into other, more usable energy forms depends on the temperature level of the waste heat, in this way an efficient use of the waste heat is possible.

As an alternative for controlling the valves 12 and the additional valves 22 by the scheduler 4, control can also be realized as a function of the temperature of the coolant at the coolant outlet 7 of each server cabinet 2 (or, in general, at the coolant outlet of each sub-unit of the computer system).

FIG. 3 shows a cooling device for processors 3 of a computer system 1 that is similarly suitable for providing waste heat of the processors 3 at a high temperature level.

Each processor 3 is in direct thermal contact with a heat exchanger 35. A control valve 32 is connected before each heat exchanger. The heat absorbers 35 and associated control valves 32 are arranged parallel in a coolant circuit 30 that also has a coolant pump 31 and a heat exchanger 33. The coolant circuit 30 is thermally coupled to a utilization circuit 34 via the heat exchanger 33.

The temperature set on one of the processors 3 results from the equilibrium between the converted electrical power in the processor 3 and the amount of heat absorbed by the heat absorber 35 from the processor 3 and dissipated through the coolant circuit 30. The control valves regulate the flow of the coolant through the corresponding, associated heat absorber 35 and thus influence the amount of heat dissipated by the processor 3. The control valves 32 are here regulated by a control loop as a function of the temperature of the heat absorber 35. Here, the control loop is designed, for example, so that below a given minimum temperature there is no or only very little coolant flow and that at a given maximum temperature, the maximum possible coolant flow is reached. In this way, independently of the electrical power converted into waste heat in the processor 3, a temperature is set on the heat absorber 35 that lies between the given minimum temperature and the given maximum temperature. The given maximum temperature is to be selected meaningfully in such a way that manufacturer default settings do not increase for the maximum temperature of the processor at which the processor is neither damaged nor exhibits increased error values. In contrast, the given minimum temperature can be selected high enough that waste heat is provided at a temperature level that can be used economically and efficiently at the heat exchanger 33 and thus in the utilization circuit 34. For example, the minimum temperature can equal 80% of the maximum permissible temperature on the processor, wherein the percentage specification relates to a temperature specification in ° C. (degrees Celsius).

In its dimensions and the position of attachment elements, the heat absorber 35 preferably corresponds to the default setting of the processor manufacturer for cooling bodies for this processor. Here, the control valve 32 can be integrated into the heat absorber and can be activated mechanically, for example, by a bimetal element, as a function of temperature. In this way, a compact fluid cooling element is produced for a processor for carrying out the method according to the invention.

As an alternative to the control loop shown in the embodiment of FIG. 3 in which the temperature of the heat absorber 35 is used as the actual value for the control, temperature control can also be performed on the basis of the temperature of the processor 3. The temperature of a processor is typically provided in digital form by the processor itself and thus can be used in a simple way for controlling an electrically activated control valve 32.

Furthermore, it is possible to provide a thermodynamic cycle for cooling the processors. In this cycle, a working medium is evaporated directly in the heat absorber 35 or an evaporator is thermally coupled to the heat exchanger 33. Due to the high latent heat of evaporation of liquids, above the evaporation temperature, the heat absorber 35 absorbs an amount of heat rising in jumps with the temperature. Due to the highly non-linear course of the absorbed amount of heat as a function of temperature, a cooling device regulating itself at the evaporation temperature is realized.

Features of the shown embodiments can also be used together in combination, for example, in that the method shown in FIG. 2 for distributing the jobs is combined with a cooling device as specified in FIG. 3.

1. A method for using waste heat of a computer system with a plurality of processors with the following steps:
distributing jobs in the computer system to the processors in such a way that processors of a first group of processors are operated with a high processor load and processors of a second group of processors are operated with only a minimal processor load and
transferring the waste heat of the processors to a device for using the waste heat.

2. The method according to claim 1 in which waste heat of processors of only the first group is transferred to the device for using the waste heat.

3. The method according to claim 2 in which another device for using the waste heat is provided, wherein the waste heat of the processors of the computer system that do not transfer their waste heat to the device for using the waste heat is transferred to the additional device for using the waste heat.

4. The method according to claim 3 in which the processors of the second group of processors are operated in a mode with lower voltage and/or lower clock rate than in the mode of normal operation.

5. The method according to claim 1 in which a virtual machine system is executed on at least one part of the processors of the computer system.

6. Method The method according to claim 1 in which the waste heat generated by the processors of the computer system is transferred at least partially into a heating system and/or a system for providing hot water.

7. The method according to claim 1 in which the waste heat generated by the processors of the computer system is fed at least partially to a thermodynamic cycle.

8. The method according to claim 7 in which the waste heat generated by the processors of the computer system drives a heat engine.

9. The method according to claim 7 in which the waste heat generated by the processors of the computer system drives an absorption-type refrigerating machine.

10. A system comprising
a computer system with a plurality of processors,
a cooling device for dissipating the waste heat of at least one part of the processors, and
a device for making use of the waste heat of the processors,
wherein the system is suitable for carrying out a method according to claim 1.

11. A method for using the waste heat of a computer system with a plurality of processors with the following steps:
dissipating waste heat from the processors through a cooling device, wherein the waste heat dissipated by the processors is controlled in such a way that the processor assumes a temperature that is greater than a given minimum temperature and
transferring the waste heat of the processors to a device for using the waste heat.

12. The method according to claim 11 in which the waste heat generated by the processors of the computer system is transferred at least partially into a heating system and/or a system for providing hot water.

13. The method according to claim 11 in which the waste heat generated by the processors of the computer system is fed at least partially to a thermodynamic cycle.

14. The method according to claim 13 in which the waste heat generated by the processors of the computer system drives a heat engine.

15. The method according to claim 13 in which the waste heat generated by the processors of the computer system drives an absorption-type refrigerating machine.

16. A system comprising
a computer system with a plurality of processors,
a cooling device for dissipating the waste heat of at least one part of the processors, and
a device for making use of the waste heat of the processors,
wherein the system is suitable for carrying out a method according to claim 11.
